(19) United States
(12) Patent Application Publication
(10) Pub. No.: US 2014/0257738 A1
(43) Pub. Date: Sep. 11, 2014

(54) HIERARCHICALLY DIVIDED SIGNAL PATH FOR CHARACTERIZING INTEGRATED CIRCUITS

(71) Applicant: GLOBALFOUNDRIES INC., Grand Cayman (KY)

(72) Inventor: Azeez J. Bhavnagarwala, Newtown, CT (US)

(73) Assignee: GLOBALFOUNDRIES INC., Grand Cayman (KY)

(21) Appl. No.: 13/792,496

(22) Filed: Mar. 11, 2013

(51) Int. Cl. G01R 31/28

(52) U.S. Cl. CPC G01R 31/2896
USPC 702/119

(57) ABSTRACT

An apparatus includes an output pad, a plurality of arrays of test devices, a hierarchy of selection devices, and address logic. The hierarchy of selection devices includes a plurality of levels coupled between the output pad and the arrays of test devices. Each test device is coupled to a selection device in a first level of the hierarchy, and the selection devices for each array are coupled to one selection device in a second level of the hierarchy. The address logic is coupled to the hierarchy of selection devices and operable to enable one selection device in each level of the hierarchy to couple a selected test device in a selected array to the output pad.

### BACKGROUND

The disclosed subject matter relates generally to integrated circuit devices and, more particularly, to a hierarchically divided signal path for characterizing integrated circuits.

Scaling of transistors and associated process structures has increased the complexity of complimentary metal oxide silicon (CMOS) technology. This complexity increases the uncertainty associated with small geometry device parameters and the number and variety of failure mechanisms that can potentially occur (e.g., at DC, at user application clock rates, across the die, across a wafer, and across a lot). The uncertainty of the electrical behavior of the devices and circuits is even larger during the initial phases of technology development of a CMOS Logic Platform. Rapidly extracting the accurate statistical distributions of DC parameters and their correct voltage, temperature, and process dependencies enables technology development and AC/DC functional failure diagnosis and optimization of the process integration to proceed at a much more rapid rate, thereby enabling lower cost and faster time to market of a CMOS Logic Platform technology.

Conventional techniques for characterizing devices are limited in density based on the amount of linear isolation provided. Parasitic leakage associated with devices not being tested affects the measurements taken for the device under test. The array size is limited by the leakage current to allow accurate measurements of the devices. While smaller array sizes permit lower off-current measurements in the range of pA, larger arrays are limited to a fraction of a nA.

This section of this document is intended to introduce various aspects of art that may be related to various aspects of the disclosed subject matter described and/or claimed below. This section provides background information to facilitate a better understanding of the various aspects of the disclosed subject matter. It should be understood that the statements in this section of this document are to be read in this light, and not as admissions of prior art. The disclosed subject matter is directed to overcoming, or at least reducing the effects of, one or more of the problems set forth above.

### BRIEF SUMMARY OF EMBODIMENTS

The following presents a simplified summary of only some aspects of embodiments of the disclosed subject matter in order to provide a basic understanding of some aspects of the disclosed subject matter. This summary is not an exhaustive overview of the disclosed subject matter. It is not intended to identify key or critical elements of the disclosed subject matter or to delineate the scope of the disclosed subject matter. Its sole purpose is to present some concepts in a simplified form as a prelude to the more detailed description that is discussed later.

One aspect of the disclosed subject matter is seen in an apparatus including an output pad, a plurality of arrays of test devices, a hierarchy of selection devices, and address logic. The hierarchy of selection devices includes a plurality of levels coupled between the output pad and the arrays of test devices. Each test device is coupled to a selection device in a first level of the hierarchy, and the selection devices for each array are coupled to one selection device in a second level of the hierarchy. The address logic is coupled to the hierarchy of selection devices and operable to enable one selection device in each level of the hierarchy to couple a selected test device in a selected array to the output pad.

Another aspect of the disclosed subject matter is seen a method that includes coupling an output pad to a plurality of arrays of test devices using a hierarchy of selection devices including a plurality of levels. Each test device is coupled to a selection device in a first level of the hierarchy, and the selection devices for each array are coupled to one selection device in a second level of the hierarchy. One selection device in each level of the hierarchy is enabled to couple a selected test device in a selected array to the output pad.

### BRIEF DESCRIPTION OF THE SEVERAL VIEWS OF THE DRAWINGS

The disclosed subject matter will hereafter be described with reference to the accompanying drawings, wherein like reference numerals denote like elements, and:

FIG. 1 is simplified block diagram of a testing device hierarchy in accordance with an embodiment of the present subject matter;

FIG. 2 is a simplified circuit diagram of an enable circuit for selecting a device under test in the hierarchy of FIG. 1; and

FIG. 3 is a simplified block diagram of a method for testing devices in accordance with an embodiment of the present subject matter.

While the disclosed subject matter is susceptible to various modifications and alternative forms, specific embodiments thereof have been shown by way of example in the drawings and are herein described in detail. It should be understood, however, that the description herein of specific embodiments is not intended to limit the disclosed subject matter to the particular forms disclosed, but on the contrary, the intention is to cover all modifications, equivalents, and alternatives falling within the spirit and scope of the disclosed subject matter as defined by the appended claims.

### DETAILED DESCRIPTION

One or more specific embodiments of the disclosed subject matter will be described below. It is specifically intended that the disclosed subject matter not be limited to the embodiments and illustrations contained herein, but include modified forms of those embodiments including portions of the embodiments and combinations of elements of different embodiments as come within the scope of the following claims. It should be appreciated that in the development of any such actual implementation, as in any engineering or design project, numerous implementation-specific decisions must be made to achieve the developers' specific goals, such as compliance with system-related and business related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure. Nothing in this application is considered critical or essential to the disclosed subject matter unless explicitly indicated as being “critical” or “essential.”

The disclosed subject matter will now be described with reference to the attached figures. Various structures, systems and devices are schematically depicted in the drawings for purposes of explanation only and so as to not obscure the disclosed subject matter with details that are well known to those skilled in the art. Nevertheless, the attached drawings are included to describe and explain illustrative examples of the disclosed subject matter. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

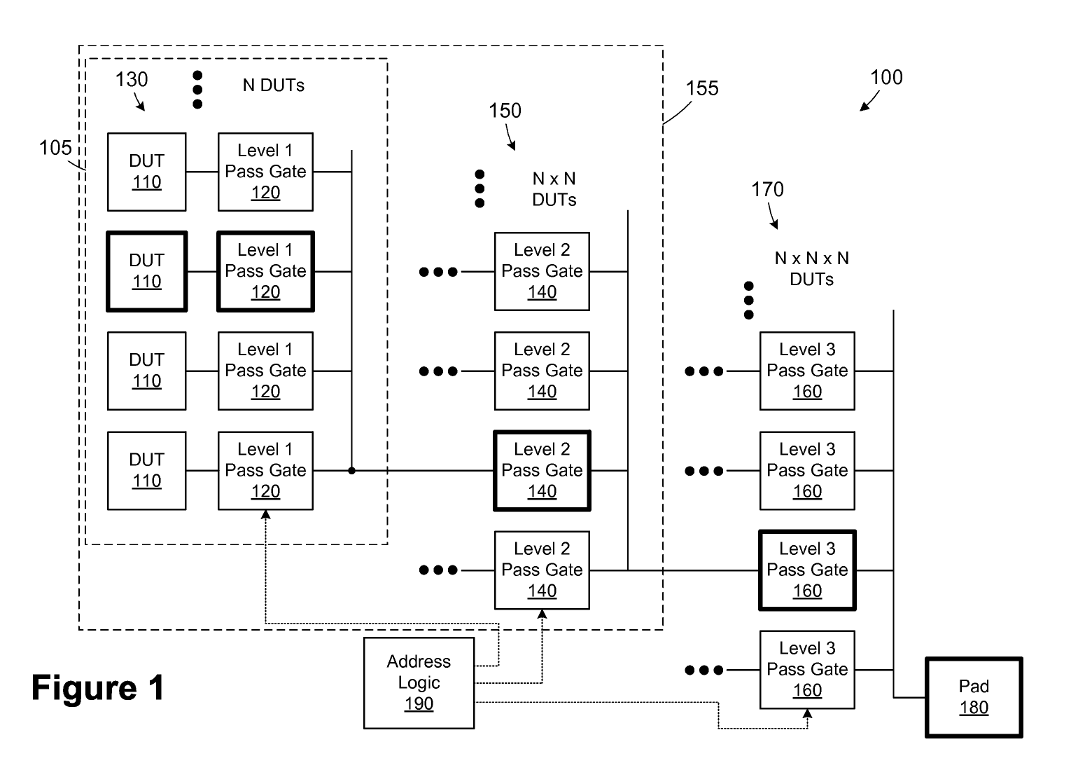

Referring now to the drawings wherein like reference numbers correspond to similar components throughout the several views and, specifically, referring to FIG. 1, the disclosed subject matter shall be described in the context of a testing device hierarchy 100. The testing device hierarchy 100 is arranged to allow testing of selected devices under test (DUT) 110, while limiting the off-current generated by DUTs 110 not being tested. The testing device hierarchy 100 includes a plurality of levels. Each DUT 110 may represent a single device, such as a transistor, or a group of devices, such as a synchronous random access memory (SRAM) bit cell. Of course, other types of DUTs 110 may be used. For SRAM bit cells, it is useful to perform statistical measurements using a large number of devices so that the devices may be characterized. For example, local stochastic distributions of cell storage node voltages may be generated during read, write, and retention modes of operation. These measurements reveal insights into terminal voltage dependencies of cell margin distributions. Other types of measurements may also be conducted. During such measurements, noise generated by the off currents of devices not being measured can impact the results. The hierarchy 100 is arranged to allow a large number of DUTs 110 to be evaluated while limiting the noise current associated with a particular measurement.

An array 105 of DUTs 110 that can be addressed for testing are located at the first level of the hierarchy 100. Each DUT 110 in the array 105 has an associated level 1 pass gate 120 for uniquely enabling a selected DUT 110 in the array 105. In a first level 130 of the hierarchy 100, N DUTs 110 are provided for each array 105. The arrays 105 in the first level 130 are replicated for each of a plurality of second level pass gates 140 in a second level 150 of the hierarchy 100. The combination of the second level pass gates 140 and their associated replicated arrays 100 define an array group 155.

In the illustrated embodiment, the second level 150 includes N second level pass gates 140. The array groups 155 defined by the first and second levels 130, 150 are replicated for each of a plurality of third level pass gates 160 in a third level 170 of the hierarchy 100. In the illustrated embodiment, the third level 150 includes N third level pass gates 160. The pass gates 160 in the third level 170 are connected to a pad 180 to allow the parameters of the selected DUT 110 to be measured.

Address logic 190 is provided for addressing a unique DUT 110 by selecting a particular level 1 pass gate 120, a particular level 2 pass gate 140, and a particular level 3 pass gate 160, as illustrated by the bold boxes in FIG. 1. The number of DUTs 110 that cause off current on the testing line is limited to N−1, as the level 1 pass gates 120 are configured to enable only one of N DUTs 110. Hence, the value of N is selected based on the maximum tolerable noise current on the signal path. For a hierarchy 100 of h levels, with N DUTs 110 in the first level array 105, and N pass gates for each level 150, 170 of the hierarchy 100, the total number of addressable DUTs 110 in the hierarchy 100 is N^{h}. It is contemplated that the number of entities in each level of the hierarchy may vary depending on the particular implementation. In the illustrated embodiment, the number of DUTs 110 in a single level 1 array 105, the number of array groups 155 in level 2, and the number of level 3 groups are all equal to the value N. This type of arrangement generally provides for easier addressing by the address logic 190, since the same decoder can be used for each level of the hierarchy 100.

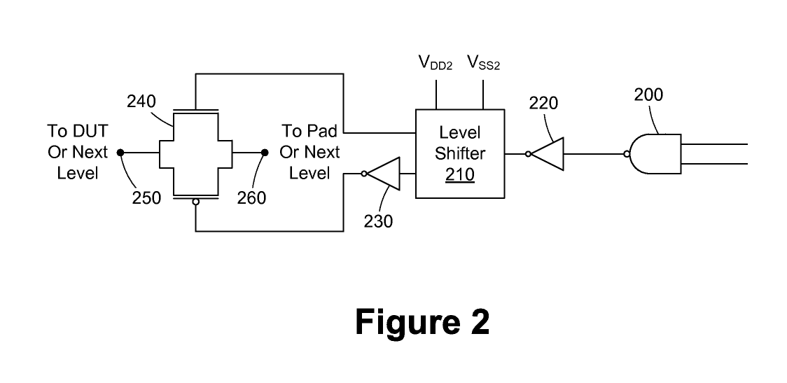

FIG. 2 is a simplified circuit diagram of an enable circuit for selecting a device under test in the hierarchy of FIG. 1. A local decoder 200 is enabled to select a particular DUT 110. The local decoder 200 may be connected to or part of the address logic 190 of FIG. 1. Secondary power supplies, V_{DD2} and V_{SS2} power a level shifter 210 that receives the enable signal from the local decoder 200 through an inverter 220. The level shifter 210 drives an enable signal and its complimentary signal via inverter 230. The level shifter 210 provides boosted enable signals for enabling a pass gate 240. In the illustrated embodiment, the pass gate 240 is a thick oxide CMOS transmission gate that lowers its on-resistance when selected and cuts off its leakage paths when deselected by virtue of the thick oxide devices and the boosted voltages provided at the gate inputs of the pass gate 240.

The pass gate 240 may be employed for any of the pass gates 120, 140, 160 in the hierarchy 100 of FIG. 1. If the pass gate 240 is in the first level (i.e., pass gate 140), a particular DUT 110 is connected to the terminal 250 of the pass gate 240 and the corresponding level 2 pass gate 160 is connected to the terminal 260. If the pass gate 240 is in the second level (i.e., pass gate 160), the associated pass gate 140 is connected to the terminal 250 of the pass gate 240 and the associated level 3 pass gate 160 is connected to the terminal 260. If the pass gate 240 is in the third level (i.e., pass gate 160 and h=3), the associated pass gate 160 is connected to the terminal 250 of the pass gate 240 and the pad 180 is connected to the terminal 260.

The use of the secondary power supplies in FIG. 2 results in improved parasitic current isolation from the unselected DUTs 110. This improvement provides for accurate determination of characteristics of the DUTs 110 deep in the sub threshold region.

If N is the maximum number of addressable DUTs given N×loff/DUT=maximum tolerable noise current on signal path, then Nh is the maximum number of addressable DUTs with h hierarchies in the decode network. The hierarchical division of the signal path enables a single macro to accomplish a much higher integration density—for example, enabling up to 6 sigma (over 1 Mb) bitcells to be fully addressable with the same leakage noise as a 1 Kb array by simply using three levels in the hierarchy as illustrated in FIG. 1 below. With this new approach, the degradation in signal path On-Resistance due to an additional CMOS transmission gate for each level of the hierarchy (3 for the example in FIG. 1) can be easily compensated by making the N and PFET devices of the Transmission gate proportionally larger while maintaining a given spec on the maximum leakage current tolerable at each hierarchy level.

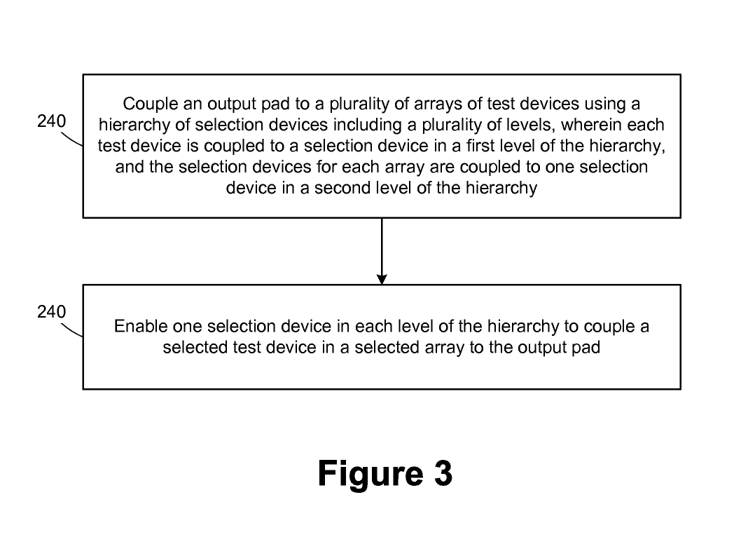

FIG. 3 is a simplified block diagram of a method for testing devices in accordance with an embodiment of the present subject matter. In method block 300, an output pad 180 is coupled to a plurality of arrays 105 of test devices 110 using a hierarchy 100 of selection devices 120, 140, 160 including a plurality of levels 130, 150, 170. Each test device 110 is coupled to a selection device 120 in a first level 130 of the hierarchy 100, and the selection devices 120 for each array 105 are coupled to one selection device 140 in a second level 150 of the hierarchy 100. In method block 310 one selection device 120, 140, 160 is enabled in each level 130, 150, 170 of the hierarchy 100 to couple a selected test device 110 in a selected array 105 to the output pad 180.

The particular embodiments disclosed above are illustrative only, as the disclosed subject matter may be modified and practiced in different but equivalent manners apparent to those skilled in the art having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the disclosed subject matter. Accordingly, the protection sought herein is as set forth in the claims below.

We claim:

1. An apparatus, comprising:
an output pad;
a plurality of arrays of test devices;
a hierarchy of selection devices including a plurality of levels coupled between the output pad and the arrays of test devices, wherein each test device is coupled to a selection device in a first level of the hierarchy, and the selection devices for each array are coupled to one selection device in a second level of the hierarchy;
address logic coupled to the hierarchy of selection devices and operable to enable one selection device in each level of the hierarchy to couple a selected test device in a selected array to the output pad.

2. The apparatus of claim 1, wherein a subset of the plurality of arrays and its associated second level selection device define an array group, wherein the array groups are replicated for each of the selection devices in the additional levels of the hierarchy.

3. The apparatus of claim 1, wherein the test devices comprise transistors.

4. The apparatus of claim 1, wherein the test devices comprise memory cells.

5. The apparatus of claim 1, wherein the first level and second level selection devices comprise pass gates.

6. The apparatus of claim 5, wherein each pass gate comprises:
a first transistor having a first gate terminal operable to receive a first enable signal from the address logic; and
a second transistor coupled in parallel with the first transistor and having a second gate terminal operable to receive a second enable signal from the address logic, wherein the second enable signal is complimentary with respect to the first enable signal.

7. The apparatus of claim 6, wherein each pass gate has an associated enable circuit, and the enable circuit comprises a level shifter operable to receive a third enable signal from the address logic at a first voltage level and generate the first enable signal at a second voltage level higher than the first voltage level, wherein the level shifter is coupled to the first gate terminal of the associated pass gate.

8. The apparatus of claim 7, wherein the level shifter is operable to generate the second enable signal at the second voltage level, and the enable circuit further comprises an inverter coupled between the level shifter and the second gate terminal.

9. The apparatus of claim 1, wherein a number of test devices in each array is equal to a number of the selection devices in the second level of the hierarchy.

10. The apparatus of claim 1, wherein a number of test devices in each array is equal to a number of selection devices in each level of the hierarchy.

11. The apparatus of claim 1, wherein a number of test devices is equal to N^{h}, where N is the number of test device in each array, and h is the number of levels in the hierarchy.

12. An apparatus, comprising:
a plurality of arrays of test devices, each array comprising:
a first level output node;
a set of test devices;
a plurality of first level selection devices, each first level selection device being coupled between one of the test devices and the first level output node for the associated array;
second level selection logic comprising a plurality of second level selection devices, each second level selection device being coupled between one of the first level output nodes of one of the arrays and a second level output node;
an output pad coupled to the second level output node; and
address logic operable to enable one of the first level selection devices and one of the second level selection devices to couple a selected test device to the output pad.

13. The apparatus of claim 12, wherein a subset of the plurality of arrays and its associated second level selection logic define an array group, and the apparatus further comprises:
a plurality of array groups; and
third level selection logic comprising a plurality of third level selection devices, each third level selection device being coupled between one of the second level output nodes of one of the array groups and a third level output node, wherein the output pad is coupled to the third level output node, and the address logic is operable to enable one of the first level selection devices, one of the second level selection devices, and one of the third level selection devices to couple the selected test device to the output pad.

14. The apparatus of claim 12, wherein a subset of the plurality of arrays and its associated second level selection device define an array group, and the apparatus further comprises additional levels of selection devices coupled between the output node and the second level output node, wherein the array groups are replicated for each of the selection devices in the additional levels, and the address logic is operable to enable one of the first level selection devices, one of the second level selection devices, and one of the selection devices in each of the additional levels to couple the selected test device to the output pad.

15. The apparatus of claim 12, wherein the test devices comprise transistors.

16. The apparatus of claim 12, wherein the test devices comprise memory cells.

17. The apparatus of claim 12, wherein the first level and second level selection devices comprise pass gates.

18. The apparatus of claim 17, wherein each pass gate comprises:
a first transistor having a first gate terminal operable to receive a first enable signal from the address logic; and
a second transistor coupled in parallel with the first transistor and having a second gate terminal operable to receive a second enable signal from the address logic, wherein the second enable signal is complimentary with respect to the first enable signal.

19. The apparatus of claim 18, wherein each pass gate has an associated enable circuit, and the enable circuit comprises a level shifter operable to receive a third enable signal from the address logic at a first voltage level and generate the first enable signal at a second voltage level higher than the first voltage level, wherein the level shifter is coupled to the first gate terminal of the associated pass gate.

20. The apparatus of claim 19, wherein the level shifter is operable to generate the second enable signal at the second voltage level, and the enable circuit further comprises an inverter coupled between the level shifter and the second gate terminal.

21. The apparatus of claim 13, wherein a number of test devices in each array is equal to a number of array groups and equal to a number of the third level selection devices.

22. A method, comprising:
coupling an output pad to a plurality of arrays of test devices using a hierarchy of selection devices including a plurality of levels, wherein each test device is coupled to a selection device in a first level of the hierarchy, and the selection devices for each array are coupled to one selection device in a second level of the hierarchy; and
enabling one selection device in each level of the hierarchy to couple a selected test device in a selected array to the output pad.

23. The method of claim 22, further comprising measuring a parameter of the selected test device.

24. The method of claim 22, further comprising:
selectively enabling different test devices in the plurality of arrays using the selection devices; and
measuring at least one parameter of the enabled test devices.
